(19) United States
(12) Patent Application Publication
(10) Pub. No.: US 2026/0171693 A1
(43) Pub. Date: Jun. 18, 2026

(54) PRESS-FIT TERMINAL AND CONNECTION STRUCTURE OF PRESS-FIT TERMINAL

(71) Applicant: SUMITOMO WIRING SYSTEMS, LTD., Mie (JP)

(72) Inventor: Satoshi SUZUKI, Mie (JP)

(21) Appl. No.: 19/129,304

(22) PCT Filed: Nov. 6, 2023
(86) PCT No.: PCT/JP2023/039834

§ 371 Date: May 13, 2025

(30) Foreign Application Priority Data
Nov. 15, 2022 (JP) 2022-182715

(51) Int. Cl. H01R 12/58; H01R 12/71; H01R 13/08

(52) U.S. Cl. CPC H01R 12/585; H01R 12/718; H01R 13/08

(57) ABSTRACT

A press-fit terminal includes a tip portion, an elastic portion, and a body portion. The elastic portion includes a pair of beam portions. The beam portions each include a front beam portion, a rear beam portion, and a press-fitted portion. A front inclined portion of the front beam portion includes, forward of a front end of an eyehole, a contact start area configured to first come into contact with an opening end portion of a through hole during press-fitting into the through hole. A peripheral edge of the eyehole includes a front hole end portion expanding outward in a width direction and rearward from a front end of the eyehole, and a rear hole end portion expanding outward in the width direction and forward from a rear end of the eyehole. An R of the rear hole end portion is smaller than an R of the front hole end portion.

### TECHNICAL FIELD

The present disclosure relates to a press-fit terminal and a connection structure of a press-fit terminal.

### BACKGROUND

The press-fit terminal disclosed in Patent Document 1 includes an elastic portion (press-fit portion) configured to be press-fitted into a through hole of a substrate in an axial direction. The elastic portion includes an eyehole, and, when press-fitted into the through hole, is elastically deformed in a direction in which the opening width of the eyehole is narrowed, thus coming into contact with an inner circumferential surface of the through hole. Press-fit terminals of this kind are also disclosed in Patent Documents 2 to 4.

### PRIOR ART DOCUMENT

### Patent Document

Patent Document 1: JP 2021-163641 A
Patent Document 2: JP 2021-163525 A
Patent Document 3: JP 2020-166954 A
Patent Document 4: JP 2004-127610 A

### SUMMARY OF THE INVENTION

### Problems to be Solved

There is concern that cracking may occur in the surface of the press-fit terminal when the press-fit terminal is elastically deformed as a result of being press-fitted into the through hole. In Patent Documents 1 to 4 described above, sufficient consideration is not given to the shape, arrangement, and the like of the eyehole in order to suppress such damage to the press-fit terminal, and there is still room for improvement in this respect. In addition, there is the challenge of reducing both the damage to the press-fit terminal and the damage to the substrate at the same time.

Therefore, it is an object of the present disclosure to suppress the damage to a press-fit terminal and a substrate during press-fitting into a through hole.

### Means to Solve the Problem

The present disclosure is directed to a press-fit terminal configured to be press-fitted into a through hole of a substrate in an axial direction, the press-fit terminal including: a tip portion; an elastic portion; and a body portion in this order from a front end side in the axial direction, wherein the elastic portion includes a pair of beam portions opposed to each other with an eyehole interposed therebetween in a width direction orthogonal to the axial direction, and configured to apply elastic reaction force to an inner circumferential surface of the through hole, the pair of beam portions each include a front beam portion extending continuously with the tip portion on the front end side in the axial direction, a rear beam portion extending continuously with the body portion on a rear end side in the axial direction, and a press-fitted portion located between the front beam portion and the rear beam portion with respect to the axial direction, the front beam portion includes, at an outer side end in the width direction, a front inclined portion inclined outward in the width direction from the tip portion side toward the press-fitted portion, the rear beam portion includes, at an outer side end in the width direction, a rear inclined portion inclined outward in the width direction from the body portion side toward the press-fitted portion, the front inclined portion includes, forward of the front end of the eyehole in the axial direction, a contact start area configured to first come into contact with an opening end portion of the through hole during press-fitting into the through hole, a peripheral edge of the eyehole includes a front hole end portion expanding outward in the width direction and rearward from the front end of the eyehole in the axial direction, and a rear hole end portion expanding outward in the width direction and forward from the rear end of the eyehole in the axial direction, and an R of the rear hole end portion is smaller than an R of the front hole end portion.

### Effect of the Invention

According to the present disclosure, it is possible to suppress the damage to a press-fit terminal and a substrate during press-fitting into a through hole.

### BRIEF DESCRIPTION OF THE DRAWINGS

FIG. 1 is a perspective view of a press-fit terminal according to Embodiment 1 of the present disclosure.

FIG. 2 is a plan view of a tip portion and an elastic portion of the press-fit terminal.

FIG. 3 is a front view of the press-fit terminal.

FIG. 4 is a diagram showing a state in which a contact start area of the press-fit terminal is in contact with an opening end portion of a through hole, with a substrate in a cutaway view.

FIG. 5 is a diagram showing a state in which the press-fit terminal is inserted into the through hole, with the substrate in a cutaway view.

### DETAILED DESCRIPTION TO EXECUTE THE INVENTION

### Description of Embodiments of the Present Disclosure

First, aspects of the present disclosure will be listed and described.

(1) A press-fit terminal according to the present disclosure is a press-fit terminal configured to be press-fitted into a through hole of a substrate in an axial direction, the press-fit terminal including: a tip portion; an elastic portion; and a body portion in this order from a front end side in the axial direction, wherein the elastic portion includes a pair of beam portions opposed to each other with an eyehole interposed therebetween in a width direction orthogonal to the axial direction, and configured to apply elastic reaction force to an inner circumferential surface of the through hole, the pair of beam portions each include a front beam portion extending continuously with the tip portion on the front end side in the axial direction, a rear beam portion extending continuously with the body portion on a rear end side in the axial direction, and a press-fitted portion located between the front beam portion and the rear beam portion with respect to the axial direction, the front beam portion includes, at an outer side end in the width direction, a front inclined portion inclined outward in the width direction from the tip portion side toward the press-fitted portion, the rear beam portion includes, at an outer side end in the width direction, a rear inclined portion inclined outward in the width direction from the body portion side toward the press-fitted portion, the front inclined portion includes, forward of the front end of the eyehole in the axial direction, a contact start area configured to first come into contact with an opening end portion of the through hole during press-fitting into the through hole, a peripheral edge of the eyehole includes a front hole end portion expanding outward in the width direction and rearward from the front end of the eyehole in the axial direction, and a rear hole end portion expanding outward in the width direction and forward from the rear end of the eyehole in the axial direction, and an R of the rear hole end portion is smaller than an R of the front hole end portion.

When the press-fit terminal is press-fitted into the through hole, the contact start area of the front inclined portion first comes into contact with the opening end portion of the through hole, whereby the front inclined portion is elastically deformed. Here, since the contact start area is located forward of the front end of the eyehole in the axial direction, compressive stress is applied to the front inclined portion. Deformation analysis has revealed that the conventional cracking in the front beam portion is due to the tensile stress generated in the front inclined portion and the like during press-fitting into the through hole. Accordingly, it is possible to prevent the occurrence of cracking in the front inclined portion to which compressive stress is applied.

When the press-fitting of the press-fit terminal into the through hole proceeds, the rear inclined portion is elastically deformed significantly, thus narrowing the opening width of the eyehole that is located toward the rear hole end portion. Here, since the R of the rear hole end portion is smaller than the R of the front hole end portion, the rear inclined portion can be elastically deformed smoothly in a direction in which the opening width is narrowed. Thus, it is possible to suppress the damage occurring to the substrate when the rear inclined portion is press-fitted into the through hole.

In this manner, according to the present disclosure, it is possible to reduce both the damage to the press-fit terminal and the damage to the substrate.

(2) It is preferable that the press-fit terminal is a plate-shaped press-fit terminal having a plate thickness of 0.2 mm or more and 0.6 mm or less, with a plate surface thereof disposed along the width direction, and, when P represents a distance, in the axial direction, from the front end of the eyehole in the axial direction to the contact start area, a relational expression of 0.05 mm≤P≤0.11 mm is satisfied.

When the distance P, in the axial direction, from the front end of the eyehole to the contact start area satisfies the above relational expression, the damage sustained by the press-fit terminal can be effectively suppressed. When the distance P is smaller than 0.05 mm, there is concern that tensile stress is generated in the front inclined portion. On the other hand, when the distance P is larger than 0.11 mm, there is concern that increased damage may occur to the substrate when the front inclined portion is press-fitted into the through hole.

(3) It is preferable that the front hole end portion is curved along an arc of a perfect circle.

The crushing of the front hole end portion can be suppressed when the press-fit terminal is press-fitted into the through hole, and it is thus possible to apply compressive stress to the front inclined portion for a longer period of time.

(4) Preferred is a connection structure of the press-fit terminal according to any one of (1) to (3), wherein the press-fitted portion is in contact with the inner circumferential surface of the through hole along the axial direction, whereby the entire eyehole fits inside the through hole.

Since the portion located toward the front inclined portion and the portion located toward the rear inclined portion of the press-fitted portion can both come into contact with the inner circumferential surface of the through hole, it is possible to increase the holding force of the press-fit terminal for the substrate.

### Details of Embodiments of the Present Disclosure

Specific examples of the present disclosure will be described below with reference to the drawings. It should be noted that the present invention is not limited to these examples, but is defined by the claims, and is intended to include all modifications which fall within the scope of the claims and the meaning and scope of equivalents thereof.

### Embodiment 1

A press-fit terminal 10 according to Embodiment 1 of the present disclosure has a shape extending in an axial direction, and is press-fitted into a through hole 91 of a substrate 90. In the following description, as for the front-rear direction, a tip side at which the press-fit terminal 10 is precedingly press-fitted into the through hole 91 is the front end side in the axial direction, or simply the front side. That is, the axial direction is the front-rear direction, and the lower side of the drawings is the front side. The left-right direction of the drawings is the width direction. Opposite sides in the width direction may also be referred to as an outer side in the width direction. An outer side in the width direction may be simply referred to as an outer side, and an inner side in the width direction may simply be referred to as an inner side. In the drawings, the front side is denoted by reference character F, and the width direction (the left side in the drawings) is denoted by reference character W. The structure of an elastic portion 12, which will be described below, will be described based on an undeformed configuration before the press-fit terminal 10 is press-fitted into the through hole 91 unless otherwise noted.

### (Structure of Press-Fit Terminal)

The press-fit terminal 10 is made of a conductive metal, and is molded, for example, by punching out a metal plate into a shape that is elongated in the axial direction. The plate surface of the press-fit terminal 10 is disposed along the width direction. The press-fit terminal 10 has a plate thickness orthogonal to the aforementioned plate surface, and is directed in the width direction.

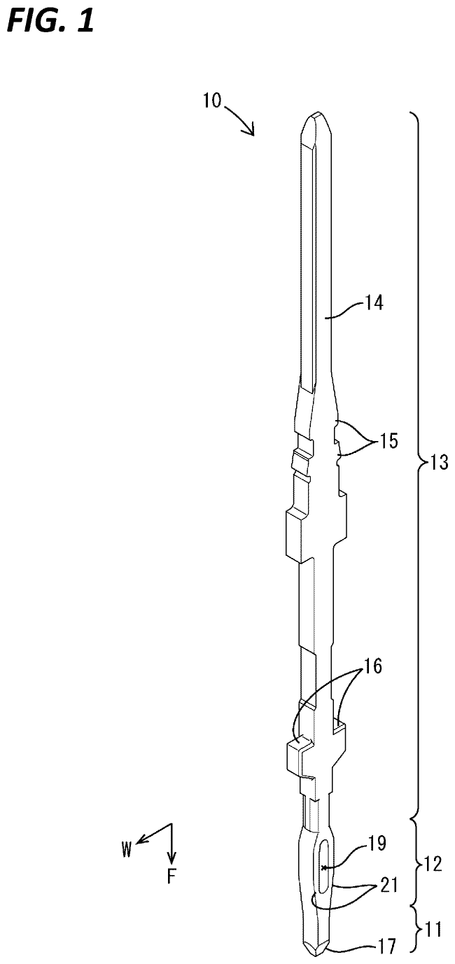

As shown in FIG. 1, the press-fit terminal 10 includes a tip portion 11, an elastic portion 12, and a body portion 13 in this order from the front end side in the axial direction.

The body portion 13 is formed over at least half the entire length of the press-fit terminal 10, and is mounted to a connector housing (not shown). The body portion 13 shown in FIG. 1 is formed linearly in the axial direction, but may be bent midway in the axial direction. The body portion 13 includes, at a rear end portion, a tab portion 14 configured to come into contact with a counterpart terminal fitting (not shown) and includes, forward of the tab portion 14, a holding portion 15 configured to be press-fitted into the connector housing. Also, the body portion 13 includes, at positions toward the elastic portion 12, a pair of projecting pieces 16 that project from opposite sides in the width direction. A rear end of each of the projecting pieces 16 is disposed along the width direction. A jig (not shown) is pressed against the rear end of each of the projecting pieces 16. The press-fit terminal 10 is press-fitted into the through hole 91 of the substrate 90 by being pressed by the jig.

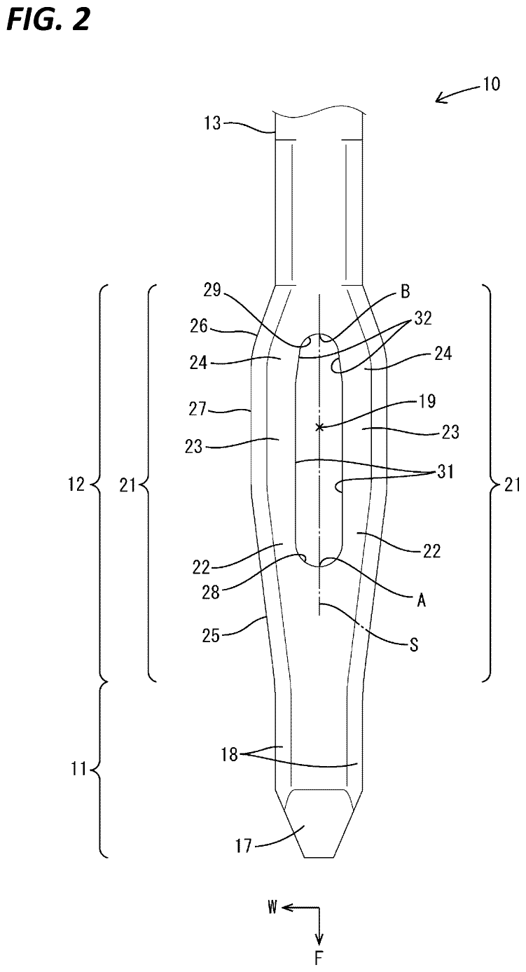

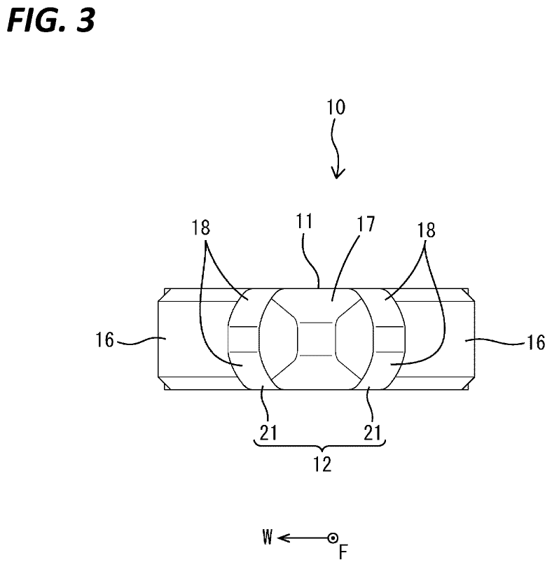

As shown in FIGS. 2 and 3, the tip portion 11 includes a reduced diameter portion 17 having a diameter reduced toward the front end side. The reduced diameter portion 17 functions as a guide for guiding the press-fit terminal 10 into the through hole 91. The tip portion 11 includes curved chamfered portions 18 at corner portions of opposite side ends in the width direction. The chamfered portions 18 are formed extending from the tip portion 11 across the elastic portion 12. Except for the reduced diameter portion 17, the tip portion 11 has a shape extending with a fixed width dimension in the axial direction.

As shown in FIG. 2, the elastic portion 12 includes, in a central portion in the width direction, an eyehole 19 extending therethrough in the plate thickness direction, and a pair of beam portions 21 at end portions on opposite ends in the width direction.

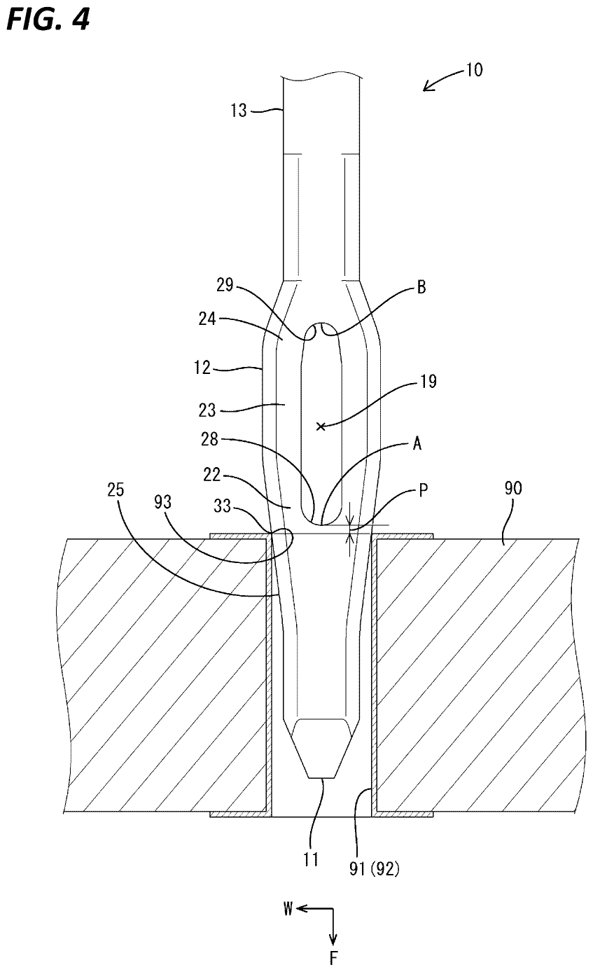

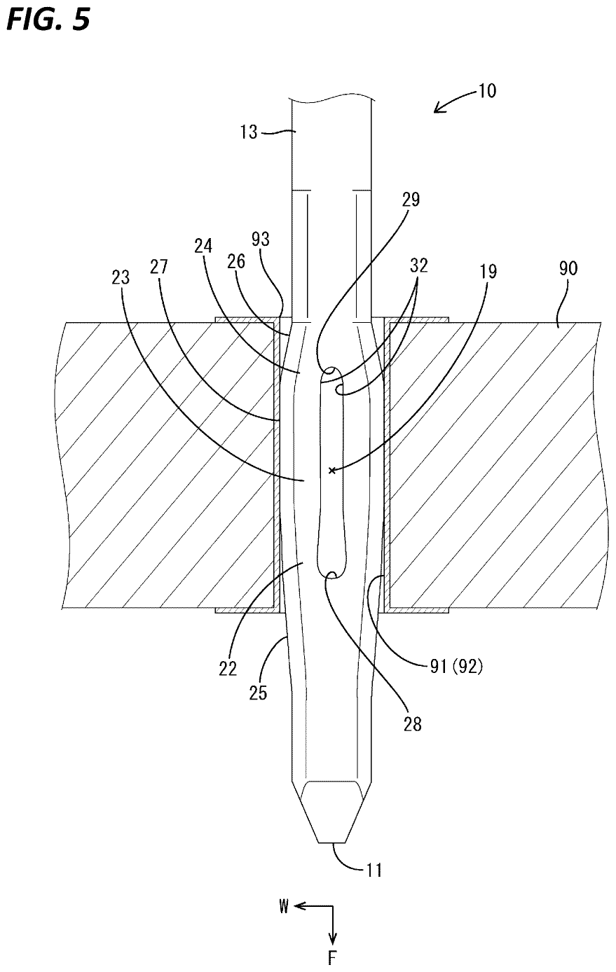

The beam portions 21 are shaped to project outward with the eyehole 19 interposed therebetween. Inner side ends of the beam portions 21 define a peripheral edge of the eyehole 19, which will be described below. During press-fitting into the through hole 91, outer side ends of the beam portions 21 come into contact with an inner circumferential surface of the through hole 91, and is electrically connected to a conductive portion 92 formed on the inner circumferential surface of the through hole 91 (see FIGS. 4 and 5).

As shown in FIG. 2, the beam portions 21 each include a front beam portion 22, a press-fitted portion 23, and a rear beam portion 24 in this order from the front end side in the axial direction.

The front beam portion 22 includes, at an outer side end, a front inclined portion 25 expanding outward from the tip portion 11 toward the press-fitted portion 23. A front end of the front inclined portion 25, or in other words, a coupling end thereof to the tip portion 11 is located forward of a front end A of the eyehole 19. A rear end of the front inclined portion 25, or in other words, a coupling end thereof to the press-fitted portion 23 is located rearward of the front end A of the eyehole 19 and forward of a central portion of the eyehole 19 in the front-rear direction.

The rear beam portion 24 includes, at an outer side end, a rear inclined portion 26 expanding outward from the body portion 13 toward the press-fitted portion 23. The inclination angle of the rear inclined portion 26 to the axial direction is larger than the inclination angle of the front inclined portion 25 to the axial direction. The length of the rear inclined portion 26 in the axial direction is shorter than the length of the front inclined portion 25 in the axial direction. A rear end of the rear inclined portion 26, or in other words, a coupling end thereof to the body portion 13 is located rearward of a rear end B of the eyehole 19. A front end of the rear inclined portion 26, or in other words, a coupling end thereof to the press-fitted portion 23 is located forward of the rear end B of the eyehole 19 and rearward of the central portion of the eyehole 19 in the front-rear direction.

The press-fitted portion 23 includes, at an outer side end, an intermediate side end portion 27 extending to be slightly inclined inward in the axial direction from the rear inclined portion 26 toward the front inclined portion 25. The intermediate side end portion 27 is disposed within the range of the eyehole 19 with respect to the axial direction.

As shown in FIG. 2, the eyehole 19 is elongated in the axial direction as a whole, and is shaped to be bilaterally symmetrical about an axis S passing through the center in the width direction. The peripheral edge of the eyehole 19 includes a front hole end portion 28 including the front end A of the eyehole 19, a rear hole end portion 29 including the rear end B of the eyehole 19, and a pair of intermediate hole edge portions 31 in the width direction that are located between the front hole end portion 28 and the rear hole end portion 29.

The front hole end portion 28 is curved from the front end A of the eyehole 19 toward the opposite sides thereof in the width direction while expanding so as to extend rearward, and has an overall arc shape. Specifically, the front hole end portion 28, as a whole, is curved along an arc of a perfect circle, and opposite ends thereof in the width direction extend continuously with the intermediate hole edge portion 31. The front inclined portion 25 is located on opposite sides of the front hole end portion 28 in the width direction.

The rear hole end portion 29 is curved from the rear end B of the eyehole 19 toward opposite sides thereof in the width direction while expanding forward, and has an overall arc shape. Specifically, the rear hole end portion 29, as a whole, is shorter than the front hole end portion 28 in the circumferential direction and the axial direction, and is curved along an arc of a perfect circle. The R of the rear hole end portion 29 is smaller than the R of the front hole end portion 28. In the present specification, an R corresponds to a radius of curvature.

The peripheral edge of the eyehole 19 includes a pair of tapered portions 32 that are tapered from the intermediate hole edge portions 31 toward opposite ends of the rear hole end portion 29 in the circumferential direction. The front inclined portion 25 is located on the opposite sides of the front hole end portion 28 and the tapered portions 32 in the width direction. The rear beam portion 24 is defined by the rear hole end portion 29, the tapered portions 32, and the rear inclined portion 26, and is shaped to extend without significantly changing a width dimension thereof.

The intermediate hole edge portions 31 are elongated in the axial direction, and are disposed parallel to each other. A rear half portion of the front inclined portion 25 and the intermediate side end portion 27 are located outward of the intermediate hole edge portions 31 in the width direction.

### (Operations of Press-Fit Terminal, and Connection Structure)

The press-fit terminal 10 is inserted from the tip portion 11 side into the through hole 91 of the substrate 90 as a result of the projecting pieces 16 being pressed by a jig (not shown). The front inclined portion 25 is inserted into the through hole 91, following the tip portion 11. As shown in FIG. 4, at the start of insertion into the through hole 91, a contact start area 33 of the front inclined portion 25 first comes into contact with an opening end portion 93 of the through hole 91 on the surface of the substrate 90. The contact start area 33 of the front inclined portion 25 is an area that first comes into contact with the opening end portion 93 of the through hole 91, and is located forward of the front end A of the eyehole 19.

After the contact start area 33 of the front inclined portion 25 has come into contact with the opening end portion 93 of the through hole 91, a further insertion of the press-fit terminal 10 causes the front beam portion 22 to slide on the opening end portion 93 of the through hole 91, whereby the front beam portion 22 is elastically deformed inward together with the press-fitted portion 23. As described above, the contact start area 33 is located forward of the front end A of the eyehole 19. Accordingly, compressive stress is applied to the front inclined portion 25 including the contact start area 33, thus suppressing the occurrence of cracking in the front inclined portion 25.

In Embodiment 1, the plate thickness of the press-fit terminal 10 is set to 0.2 mm to 0.6 mm, preferably 0.3 mm to 0.5 mm, and more preferably 0.4 mm. In this case, P (see FIG. 4) represents the distance, in the axial direction, from the front end A of the eyehole 19 to the contact start area 33, P is set to be within the range of 0.05 mm≤P≤0.11 mm. It has been confirmed that, if a press-fit terminal 10 having a plate thickness of 0.2 mm to 0.6 mm satisfies a relational expression of 0.05 mm≤P≤0.11 mm, this is effective in suppressing the occurrence of cracking in the press-fit terminal 10. That is, when the distance P is smaller than 0.05, tensile stress is applied to the front inclined portion 25, thus making it difficult to suppress the occurrence of cracking. On the other hand, when the distance P is greater than 0.11, there is concern that increased damage may occur to the substrate 90 when the front inclined portion 25 is press-fitted into the through hole 91. Accordingly, P is configured to be within the range of 0.05 mm≤P≤0.11 mm.

When the insertion of the press-fit terminal 10 into the through hole 91 further proceeds, the intermediate side end portion 27 comes into contact with the inner circumferential surface of the through hole 91, thus causing the press-fitted portion 23 to be elastically deformed inward significantly. When the tapered portions 32 of the eyehole 19 are deformed so as to approach each other, the rear beam portion 24 is also elastically deformed inward accordingly (see FIG. 5). As described above, the R of the rear hole end portion 29 is smaller than the R of the front hole end portion 28. Accordingly, the rear inclined portion 26 can be elastically deformed smoothly in a direction in which the opening width of the eyehole 19 that is located toward the rear hole end portion 29, thus making it possible to suppress the damage occurring to the substrate 90 when the rear inclined portion 26 is press-fitted into the through hole 91.

In Embodiment 1, the insertion force in an insertion final state in which the area of the press-fitted portion 23 that is located toward the rear beam portion 24, or the rear beam portion 24 comes into contact with the opening end portion 93 of the through hole 91 is smaller than the insertion force in an insertion initial state in which the contact start area 33 of the front beam portion 22 comes into contact with the opening end portion 93 of the through hole 91. Due to such a smaller insertion force of the press-fit terminal 10 in the insertion final state, it is possible to reduce the damage caused to the substrate 90 when the press-fit terminal 10 is attempted to be inserted off-axis into the through hole 91.

When the press-fit terminal 10 is inserted into the through hole 91 at an appropriate depth, the entire eyehole 19 is disposed so as to fit inside the through hole 91 as shown in FIG. 5. The press-fitted portion 23 of the beam portion 21 comes into contact with the inner circumferential surface of the through hole 91 along the axial direction, thus applying elastic reaction force to the inner circumferential surface of the through hole 91. This allows the press-fit terminal 10 to be stably held by the substrate 90, and be electrically connected to the conductive portion 92.

As described thus far, according to Embodiment 1, the contact start area 33 of the front inclined portion 25 is located forward of the front end A of the eyehole 19. Accordingly, compressive stress can be applied to the front inclined portion 25 when the press-fit terminal 10 is press-fitted into the through hole 91. Thus, it is possible to prevent the occurrence of cracking in the front inclined portion 25. In addition, the R of the rear hole end portion 29 is smaller than the R of the front hole end portion 28, and therefore, the rear beam portion 24 can be elastically deformed inward smoothly. Thus, it is possible to suppress the damage caused to the substrate 90 when the rear inclined portion 26 is press-fitted into the through hole 91. As a result, in Embodiment 1, it is possible to suppress the damage to the press-fit terminal 10 and the substrate 90 during press-fitting into the through hole 91.

Since the front hole end portion 28 is curved along an arc of a perfect circle, the crushing of the front hole end portion 28 can be suppressed when the press-fit terminal 10 is press-fitted into the through hole 91, and it is thus possible to apply compressive stress to the inclined portion 25 for a longer period of time.

### Other Embodiments of the Present Disclosure

It should be appreciated that the embodiment presently disclosed is in all respects illustrative and not limiting.

In Embodiment 1, the press-fit terminal is shaped to be bilaterally symmetrical with respect to the axis passing through the center in the width direction. In contrast, in other embodiments, the press-fit terminal may be shaped to be bilaterally asymmetrical with respect to the axis passing through the center in the width direction. For example, the elastic portion may be shaped to be bilaterally asymmetrical.

### LIST OF REFERENCE NUMERALS

10 Press-fit terminal
11 Tip portion
12 Elastic portion
13 Body portion
14 Tab portion
15 Holding portion
16 Projecting piece
17 Reduced diameter portion
18 Chamfered portion
19 Eyehole
21 Beam portion
22 Front beam portion
23 Press-fitted portion
24 Rear beam portion
25 Front inclined portion
26 Rear inclined portion
27 Intermediate side end portion
28 Front hole end portion
29 Rear hole end portion
31 Intermediate hole edge portion
32 Tapered portion
33 Contact start area
90 Substrate
91 Through hole
92 Conductive portion
93 Opening end portion
A Front end of eyehole
B Rear end of eyehole
P Distance
S Axis

1. A press-fit terminal configured to be press-fitted into a through hole of a substrate in an axial direction, the press-fit terminal comprising:
a tip portion; an elastic portion; and a body portion in this order from a front end side in the axial direction, wherein
the elastic portion includes a pair of beam portions opposed to each other with an eyehole interposed therebetween in a width direction orthogonal to the axial direction, and configured to apply elastic reaction force to an inner circumferential surface of the through hole,
the pair of beam portions each include a front beam portion extending continuously with the tip portion on the front end side in the axial direction, a rear beam portion extending continuously with the body portion on a rear end side in the axial direction, and a press-fitted portion located between the front beam portion and the rear beam portion with respect to the axial direction,
the front beam portion includes, at an outer side end in the width direction, a front inclined portion linearly inclined outward in the width direction from the tip portion side toward the press-fitted portion,
the rear beam portion includes, at an outer side end in the width direction, a rear inclined portion linearly inclined outward in the width direction from the body portion side toward the press-fitted portion,
an acute inclination angle of the rear inclined portion in the axial direction is larger than an acute inclination angle of the front inclined portion in the axial direction,
a length of the rear inclined portion in the axial direction is shorter than a length of the front inclined portion in the axial direction,
the front inclined portion includes, forward of the front end of the eyehole in the axial direction, a contact start area configured to first come into contact with an opening end portion of the through hole during press-fitting into the through hole,
a peripheral edge of the eyehole includes a front hole end portion expanding outward in the width direction and rearward from the front end of the eyehole in the axial direction, and a rear hole end portion expanding outward in the width direction and forward from the rear end of the eyehole in the axial direction, and
an R of the rear hole end portion is smaller than an R of the front hole end portion.

2. The press-fit terminal according to claim 1, wherein
the press-fit terminal is a plate-shaped press-fit terminal having a plate thickness of 0.2 mm or more and 0.6 mm or less, with a plate surface thereof disposed along the width direction, and,
when P represents a distance, in the axial direction, from the front end of the eyehole in the axial direction to the contact start area,
a relational expression of
$$0.05 mm \leq P \leq 0.11 mm$$
is satisfied.

3. The press-fit terminal according to claim 1, wherein
both the front hole end portion and the rear hole end portion are curved along an arc of a perfect circle,
the peripheral edge of the eyehole includes an intermediate hole edge portion extending between the front hole end portion and the rear hole end portion in the axial direction, and a tapered portion linearly inclined inward in the width direction from the intermediate hole edge portion toward the rear hole end portion,
the rear beam portion is defined by the rear hole end portion, the tapered portion, and the rear inclined portion, and
the front hole end portion extends continuously with the intermediate hole edge portion.

4. A connection structure of the press-fit terminal according to claim 1, wherein
the press-fitted portion is in contact with the inner circumferential surface of the through hole along the axial direction, whereby the entire eyehole fits inside the through hole.
